(19) United States
(12) Patent Application Publication
(10) Pub. No.: US 2021/0202470 A1
(43) Pub. Date: Jul. 1, 2021

(54) MOSFET WITH INTEGRATED ESD PROTECTION DIODE HAVING ANODE ELECTRODE CONNECTION TO TRENCHED GATES FOR INCREASING SWITCH SPEED

(71) Applicant: Nami MOS CO., LTD., New Taipei City (TW)

(72) Inventor: Fu-Yuan HSIEH, New Taipei City (TW)

(73) Assignee: Nami MOS CO., LTD., New Taipei City (TW)

(21) Appl. No.: 16/731,114

(22) Filed: Dec. 31, 2019

(51) Int. Cl. H01L 27/02; H01L 29/06; H01L 29/866; H01L 29/78; H01L 29/417; H01L 29/423; H01L 23/00

(52) U.S. Cl. CPC H01L 27/0255; H01L 29/0696; H01L 29/866; H01L 29/7813; H01L 29/41741; H01L 2224/05552; H01L 24/06; H01L 24/05; H01L 29/7811; H01L 2224/0603; H01L 29/4236

(57) ABSTRACT

A trench semiconductor power device integrated with ESD clamp diodes for optimization of total perimeter of the ESD clamp diodes, wherein the ESD clamp diodes comprise multiple back to back Zener diodes with alternating doped regions of a first conductivity type next to a second conductivity type, wherein anode electrode of the ESD clamp diodes connects with trenched gates in active area for gate resistance reduction.

### FIELD OF THE INVENTION

This invention relates generally to the cell structure, device configuration and layout of semiconductor power devices. More particularly, this invention relates to an improved cell structure and device configuration to manufacture a trench semiconductor power device with integrated ESD protection diode having anode electrode connection to trenched gates for increasing switch speed.

### BACKGROUND OF THE INVENTION

Conventional layouts and device structures for manufacturing a trench semiconductor power device integrated with Gate-Source ESD clamp diodes for providing an ESD protection still have a limitation. Prior arts disclosed in U.S. Pat. No. 8,053,808 (as shown in FIG. 1A and FIG. 1B) only has one kind ESD diode region between gate metal pad and source metal pad. For small devices with high ESD rating, there is no much space budget, requiring increasing total peripheral length of the ESD diodes on gate metal pad for ESD capability enhancement.

To improve the space limitation, another two prior arts also disclosed in above U.S. Pat No. as shown in FIGS. 1C and 1D. FIG. 1C is a top view of a MOSFET (Metal Oxide Semiconductor Field Effect Transistor) device 100 which includes a gate metal pad 110 connected to a gate metal runner 125 disposed on the peripheral edges of the device 100 and a source metal pad 120. There is a metal gap 115 opened between the source metal pad 110 and the gate metal pad 110′ and the gate metal runner 125. Gate-Source ESD clamp diodes 130 are connected between the gate metal runner 125 and the source metal pad 120. FIG. 1D is a top view of another MOSFET device 200 that includes a gate metal pad 212 connected to gate metal runners 213 and a source metal pad 211 with a metal gap 214 disposed between them. Unlike the MOSFET device 100 in FIG. 1C, the MOSFET 200 in FIG. 1D further comprises poly-silicon resistors 215 together with Gate-Source ESD clamp diodes 216 which are connected between the gate metal runner 213 and the source metal pad 211. And furthermore, in FIG. 1D, there is another kind of Gate-Source ESD clamp diode 217 which is connected between the gate metal pad 212 and the source metal pad 211. All the Gate-Source ESD clamp diodes in FIG. 1C and FIG. 1D comprise multiple back to back Zener diodes with alternating n+ doped regions next to p+ doped regions, wherein the alternating n+ doped regions and p+ doped regions have a stripe structure which would have a leakage path along an edge of the Gate-Source ESD clamp diodes because the dry poly-silicon etch step in the manufacturing process would damage the edge of the Gate-Source ESD clamp diodes. Therefore, there are only two types of Gate-Source ESD clamp diodes in the prior art: a first type is formed between the gate metal pad and the source metal pad, and a second type is formed between the source metal pad and the gate metal runner. Especially for small-size devices, there is not much space budget for the Gate-Source ESD clamp diodes due to the size limitation of dies, which requires increasing the total perimeter of the Gate-Source ESD clamp diodes for ESD capability enhancement.

Please refer to FIG. 1E for an improved layout disclosed in U.S. Pat. No. 8,466,514. There are four types of Gate-Source ESD clamp diodes for providing an ESD protection between a source electrode and a gate electrode of the trench semiconductor power device 300: a first type Gate-Source ESD clamp diode (ESD1, as illustrated) connected between the gate metal pad 301 and the source metal pad 303; a second type Gate-Source ESD clamp diode (ESD2, as illustrated) connected between the gate metal pad 301 and the source metal runner 304; a third type Gate-Source ESD clamp diode (ESD3, as illustrated) connected between the gate metal runner 302 and the source metal pad 303; and a fourth type Gate-Source ESD clamp diode (ESD4, as illustrated) connected between the gate metal runner 302 and the source metal runner 304. Therefore, the improved layout and device structure according to the present invention comprises two more types of Gate-Source ESD clamp diodes comparing to the prior arts as shown in FIGS. 1A-1D that have only two types of Gate-Source ESD clamp diodes, which increases the total perimeter of the Gate-Source ESD clamp diodes to enhance ESD capability especially for small devices. However, gate metal runner surrounding active area as anode of ESD diode does not connecting to trench gate resulting in slow switching speed due to high gate resistance Rg, especially for P channel trench MOSFET.

Therefore, there is still a need in the art of the semiconductor power device integrated with Gate-Source ESD clamp diodes, to provide a novel cell structure, device configuration and layout that would further optimize total perimeter of the Gate-Source ESD clamp diodes for ESD capability enhancement, reduce the gate resistance Rg and increase the switching speed without sacrificing other performances and improve other characteristics of the semiconductor power device.

### SUMMARY OF THE INVENTION

It is therefore an aspect of the present invention to provide a semiconductor power device so that the total perimeter of the Gate-Source ESD clamp diodes is increased for ESD capability enhancement without sacrificing other performances of the semiconductor power device. According to the present invention, there is provided a semiconductor power device integrated with Gate-Source ESD clamp diodes formed on a semiconductor silicon layer, comprising a substrate of a first conductivity type: an epitaxial layer of the first conductivity type grown on the substrate, wherein the epitaxial layer having a lower doping concentration than the substrate; a plurality of transistor cells in an active area, and multiple back to back Zener diodes with alternating doped regions of a first conductivity type next to a second conductivity type in the Gate-Source ESD clamp diodes. The trench semiconductor power device further comprises: a plurality of first type trenched gates surrounded by source regions of the first conductivity type encompassed in body regions of the second conductivity type; a plurality of trenched source-body contacts opened through the source regions and extending into the body regions, filled with a contact metal plug therein and connected to a front metal serving as a source metal pad. The Gate-Source ESD clamp diodes further comprises: a gate metal pad connected to a first type gate metal runner having poly-silicon layer underneath as anode electrode of the gate-source ESD clamp diodes surrounding a peripheral region of the semiconductor power device; a first type Gate-Source ESD clamp diode connected between the gate metal pad and the source metal pad; a second type Gate-Source ESD clamp diode connected between the first type gate metal runner and the source metal pad; The first type gate metal runner is extended into the active area and connected to the first type trench gates for gate resistance reduction. The first type gate metal runner extended into active area connecting to the first type trench gate from the first type gate metal runner surrounding the peripheral region of power device. The first type gate metal runner extended to active area and connected to the first type trench gates through at least one second type gate metal runner without having the undoped poly-silicon layer underneath.

According to another aspect, the invention also features a semiconductor power device comprises: source metal pad connected to at least one source metal runner disposed between the gate metal pad and the gate metal runner, and separated from the gate metal pad and the gate metal runner by a metal gap, wherein the source metal runner does not have the first type trenched gates underneath; a third type Gate-Source ESD clamp diode connected between the gate metal pad and the source metal runner; and a fourth type Gate-Source ESD clamp diode connected between the source metal runner and the gate metal runner.

According to another aspect, the invention also features a semiconductor power device comprises: at least one body-dopant region of the second conductivity type with floating voltage in a termination area, wherein the body-dopant region is formed simultaneously as the body regions; a source-dopant region of the first conductivity type formed near an edge of the semiconductor power device, wherein the source-dopant region is formed simultaneously as the source regions; a trenched drain contact filled with the contact metal plug and penetrating through the source-dopant region, and further extended into the semiconductor silicon layer; an ohmic contact doped region of the second conductivity type surrounding at least bottom of the trenched drain contact underneath the source-dopant region; and the ohmic contact doped region has a higher doping concentration than the body regions.

Some preferred embodiments include one or more detail features as followed: each of the alternating doped regions of the Gate-Source ESD clamp diodes has a closed ring structure; the body regions are formed underneath the Gate-Source ESD clamp diodes, and are further extended between every two adjacent of second type trenched gates functioning as etch-buffer trenched gates, and the etch-buffer trenched gates are penetrating through the body regions and disposed right below trenched ESD contacts in the Gate-Source ESD clamp diodes, wherein the etch-buffer trenched gates have trench width greater than the trenched ESD contacts for prevention of gate-body shortage; there is no front metal covering a top surface of the contact metal plug in the trenched drain contact; multiple third type trenched gates having floating voltage in a termination area are comprised; the contact metal plug is a tungsten layer padded with a barrier metal layer of Ti/TiN or Co/TiN; the front metal is Al alloys overlying a resistance-reduction layer of Ti or Ti/TiN; the first type trench gates are single trench gate; the first type trench gates are shielded trenched gate having dual gate electrodes comprising a gate electrode disposed in the upper portion and a shielded electrode disposed in the lower potion, wherein the gate electrode and the shielded electrode insulated from each other by an inter-electrode insulation layer; the first conductivity type is N type and second conductivity type is P type; the first conductivity type is P type and second conductivity is N type.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a top view of a prior art for a MOSFET device.

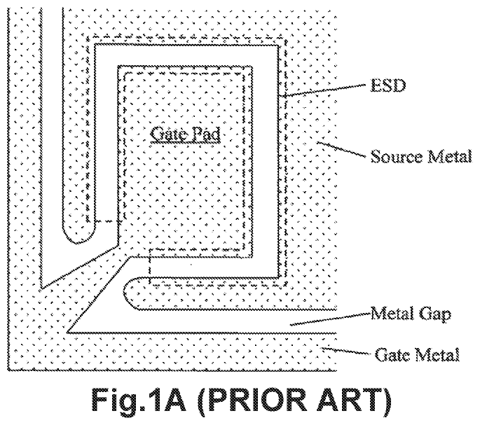

FIG. 1B is a top view of a prior art for another MOSFET device.

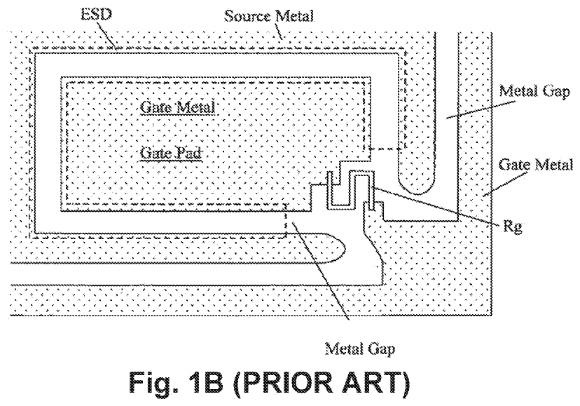

FIG. 1C is a top view of a prior art for another MOSFET device.

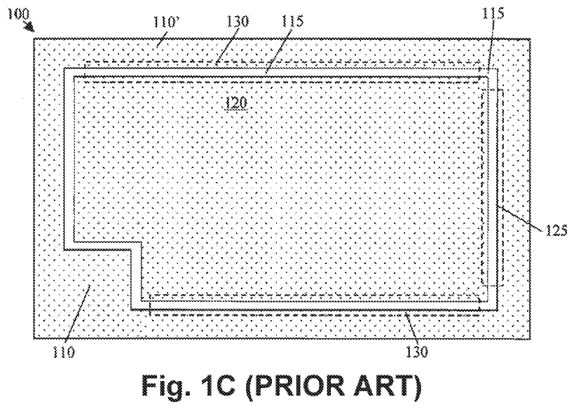

FIG. 1D is a top view of a prior art for another MOSFET device.

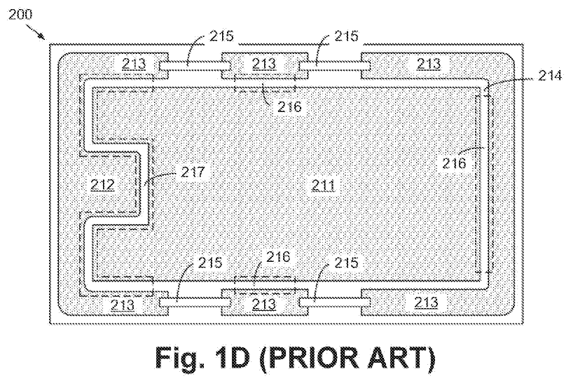

FIG. 1E is a top view of a prior art for another MOSFET device.

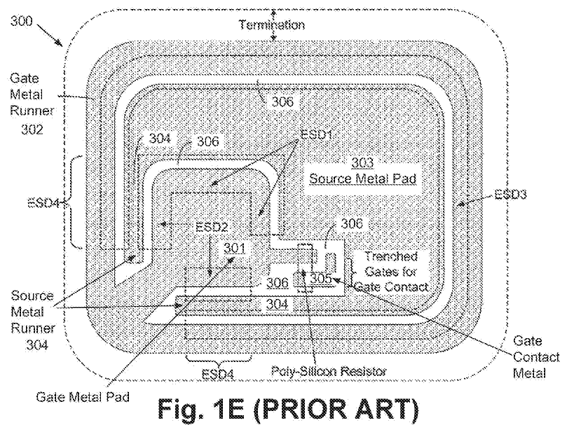

FIG. 2A is a top view of a preferred embodiment for a trench semiconductor power device according to the present invention.

FIG. 2B is a top view of another preferred embodiment for showing the doped regions of ESD diodes on gate metal pad and peripheral poly silicon areas according to the present invention.

FIG. 2C is a top view of another preferred embodiment according to the present invention.

FIG. 2D is a top view of another preferred embodiment according to the present invention.

FIG. 3 is a top view of another preferred embodiment according to the present invention.

FIG. 4 is a top view of another preferred embodiment according to the present invention.

FIG. 5 is a top view of another preferred embodiment according to the present invention

FIG. 6A is a cross-section view showing a preferred E to G cross section of FIG. 3.

FIG. 6B is a cross-section view showing another preferred E to G cross section of FIG. 3.

FIG. 7 is a cross-section view showing another preferred E to G cross section of FIG. 3.

FIG. 8A is a cross-section view showing another preferred E to G cross section of FIG. 3.

FIG. 8B is a cross-section view showing another preferred E to G cross section of FIG. 3.

FIG. 9 is a cross-section view showing another preferred E to G cross section of FIG. 3

### DETAILED DESCRIPTION OF THE EMBODIMENTS

In the following Detailed Description, reference is made to the accompanying drawings, which forms a part hereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

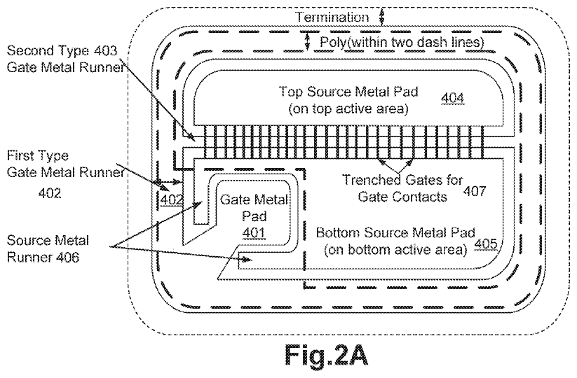

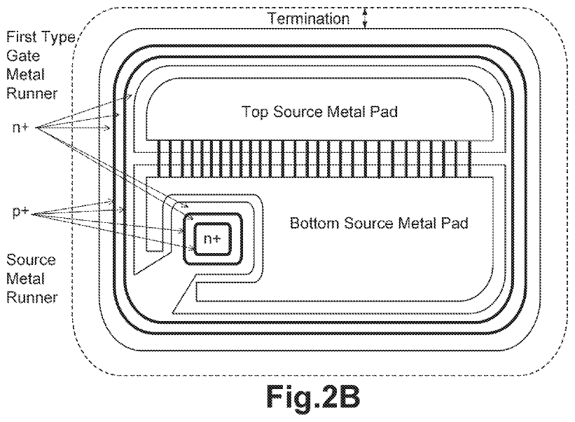

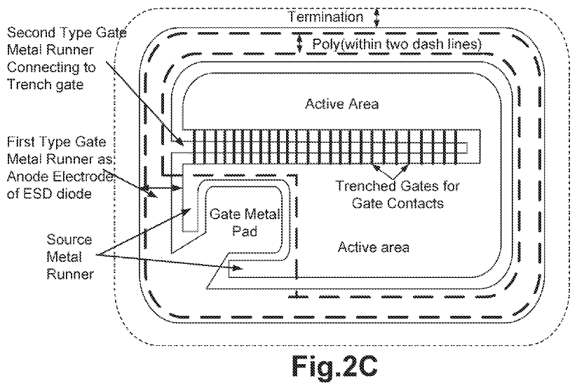

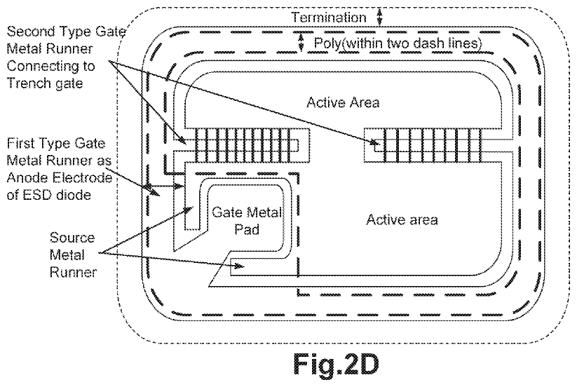

Please refer to FIG. 2A for a preferred embodiment of this invention, wherein a trench semiconductor power device is shown integrated with Gate-Source ESD clamp diodes. The trench semiconductor power device includes a gate metal pad 401 for gate wire bonding with a first type gate metal runner 402 having a poly-silicon layer underneath as anode electrode of ESD diode surrounding a peripheral region of the trench semiconductor power device, and a second type gate metal runner 403 without having the poly-silicon layer underneath connecting to trenched gates 407, wherein the trenched gated 407 are for gate contacts, and the second type gate metal runner 403 is between two active areas from one side of anode electrode of ESD diode to opposite side of the anode electrode connecting to trench gates. The trench semiconductor power device also includes a top source metal pad 404 on top active area and a bottom source metal pad 405 on bottom active area for source wire bonding with a source metal runner 406 surrounding a peripheral region of the gate metal pad 401, wherein the bottom source metal pad 405 with the source metal runner 406, the gate metal pad 401 with the first type gate metal runner 402, the second type gate metal runner 403 with the trenched gates, and the top source metal pad 404 are composed of Al alloys as a front metal overlying a resistance-reduction layer of Ti or Ti/TiN. The source metal pad is connected to a plurality of source regions and body regions surrounding a plurality of first type trenched gates underneath an active area while the source metal runner does not have the first type trenched gates underneath. The gate metal pad 401 having a square or circular shape is for gate wire bonding, and the source metal pad is for source wire bonding. There are four types of Gate-Source ESD clamp diodes for providing an ESD protection between a source electrode and a gate electrode of the trench semiconductor power device: a first type Gate-Source ESD clamp diode connected between the gate metal pad and the bottom source metal pad; a second type Gate-Source ESD clamp diode connected between the source metal pad and the gate metal runner; a third type Gate-Source ESD clamp diode connected between the gate metal pad and the source metal runner; and a fourth type Gate-Source ESD clamp diode connected between the gate metal runner and the source metal runner. Therefore, the improved layout and device structure according to the present invention comprises anode electrode of the ESD clamp diodes connects with trench gates in active area, which results in gate resistance reduction.

FIG. 2B is a top view of device configuration of doped regions of ESD diodes on gate metal pad and peripheral poly silicon areas. The Gate-Source ESD clamp diodes comprise multiple back to back Zener diodes with alternating n+ doped regions next to p+ doped regions formed under the gate metal pad 401 and the first type gate metal runner 402 of the trench semiconductor power device as shown in FIG. 2A, wherein the multiple doped regions have multiple n+ and p+ closed rings on a poly-silicon layer, that would not touch edges of the Gate-Source ESD clamp diodes, therefore, the improved layout and device structure according to the present invention would not have the leakage path that exists in the prior art. The Gate-Source ESD clamp diodes further comprise trenched ESD contacts filled with a contact metal plug and extending into the n+ doped regions on two sides of each of the Gate-Source ESD clamp diodes for an N-channel trench semiconductor power device.

Please refer to FIG. 2C for another preferred embodiment of this invention, which is similar to that shown in FIG. 2A, except that second type gate metal runner disclosed in this invention extended from one side of the anode electrode into active area connecting to trenched gates.

Please refer to FIG. 2D for another preferred embodiment of this invention, which is similar to that shown in FIG. 2A, except that the second type gate metal runner disclosed in this invention extended from two sides of the anode electrode of ESD diode into active area connecting to trenched gates.

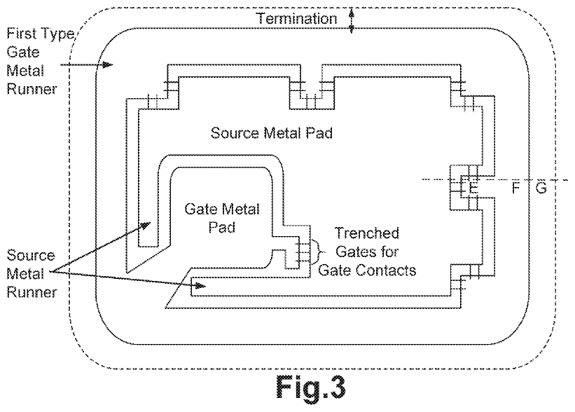

FIG. 3 is a top view of another preferred embodiment for a trench semiconductor power device according to the present invention. Besides the gate metal pad connects to trenched gates, the first type gate metal runner as the anode electrode of ESD diode surrounding active area also connects to trenched gates on device corners and/or between device corners.

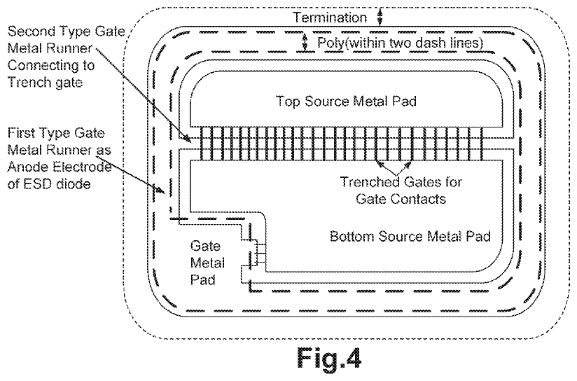

FIG. 4 is a top view of another preferred embodiment according to the present invention, which is similar as the structure disclosed in FIG. 2A, except that the structure in this invention has no source metal runners near gate metal pad.

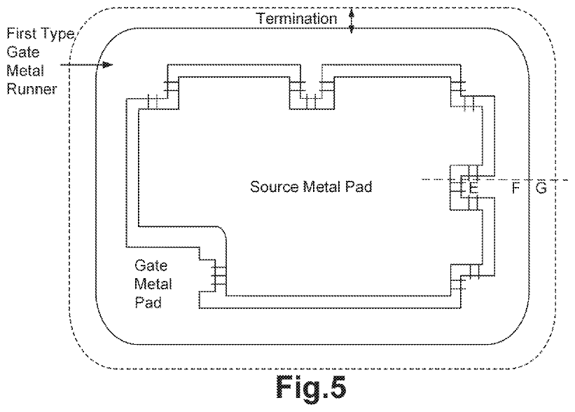

FIG. 5 is a top view of another preferred embodiment according to the present invention, which is similar as the structure disclosed in FIG. 2C, except that the structure in this invention has no source metal runners nearby gate metal pad. All of the above inventions significantly reduce Rg.

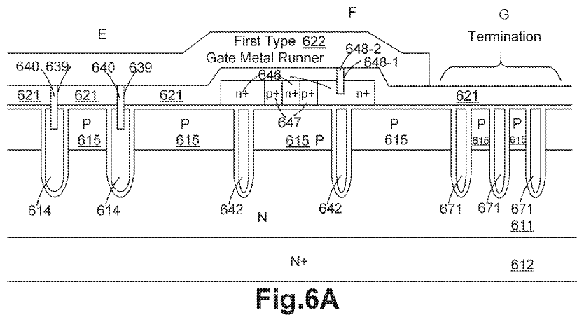

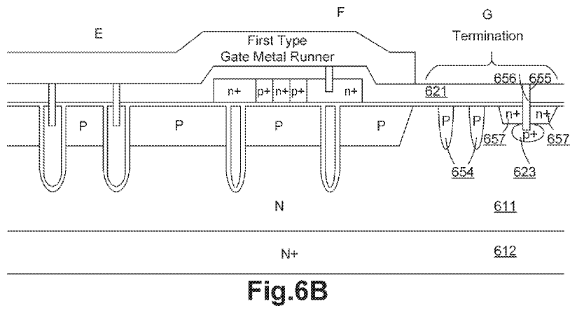

Please refer to FIG. 6A for an E-F-G cross-section view of FIG. 3, which is comprises of single trench gate MOSFET (N channel) with trenched termination. The structure is formed in a semiconductor silicon layer which can be implemented by comprising an N epitaxial layer 611 above a heavily doped N+ substrate 612. A plurality of trenched gates 614, 642 and 671 are formed spaced apart by P body regions 615 and extending into the N epitaxial layer 611. A gate-source ESD clamp diode for providing an ESD protection comprises multiple back to back Zener diodes with alternating n+ doped regions 646 next to p+ doped regions 647, and further comprises trenched ESD contacts 648-1 filled with the contact metal plugs 648-2, for example, a tungsten layer padded by a barrier metal layer of Ti/TiN or Co/TiN or Ta/TIN, is implemented through a contact interlayer 621, extending into the n+ regions 646 of the Gate-Source ESD clamp diode. The trenched ESD contact 648-1 of the Gate-Source ESD clamp diode is connected to the first type gate metal runner 622. Right below the trenched ESD contacts 648-1, there is the etch-buffer trenched gate 642 which serves as the buffer layer for prevention of gate-body shortage. A trenched body contact 639 filled with the contact metal plug 640, which are the same as the contact metal plug 648-2 is implemented through the contact interlayer 621 and extending into the etch-buffer trenched gate 614 to connect the trenched gate 614 to the first type gate metal runner 622 onto the contact interlayer 621. A termination area comprises a plurality of multiple third type trenched gates 671 being spaced apart by the P body regions 615, wherein the multiple third type trenched gates 671 having a same structure as the first type trenched gates 642 have floating voltage to function as trenched floating rings for the termination area.

Please refer to FIG. 6B for another E-F-G cross-section view of FIG. 3, which is comprised of single trench gate MOSFET with multiple P body floating rings. The invention disclosed in FIG. 6B is same as that in FIG. 6A, except for the termination area: P body-dopant regions 654 in the N epitaxial layer 611 and a trenched drain contact 655 filled with the contact metal plug 656 penetrating through the contact interlayer 621, an n+ source-dopant region 657 and extending into the N epitaxial layer 611 with the p+ ohmic contact doped region 623 surrounding at least its bottom, wherein the n+ source-dopant region 657 can reduce the contact resistance between the N epitaxial layer 611 and the contact metal plug 656 filled in the trenched drain contact 655, wherein the trenched drain contact 655 is finally connected to a drain region in the N epitaxial layer 611. There is no front metal covering on top surface of the contact metal plug 656 in the trenched drain contact 655.

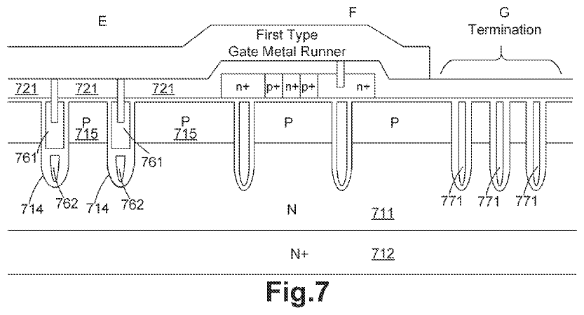

Please refer to FIG. 7 for another E-F-G cross-section view of FIG. 3, which is comprises of shielded gate trench MOSFET with trench filed plate as termination. The structure is quite similar to that disclosed in FIG. 6A, except for dual electrodes comprising a gate electrode 761 and a shielded gate electrode 762 in trenches 714 and the trench field plates 771 in termination. The first type gate metal runner is extended into active area and connected to the gate electrode 761 of the first type trenched gates.

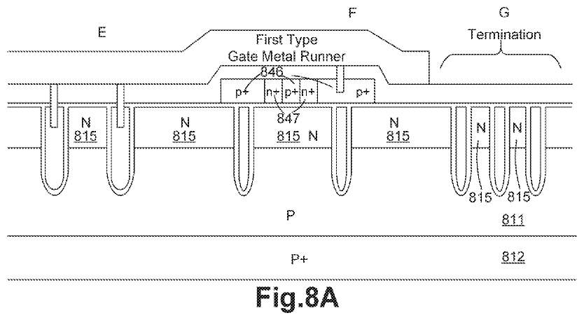

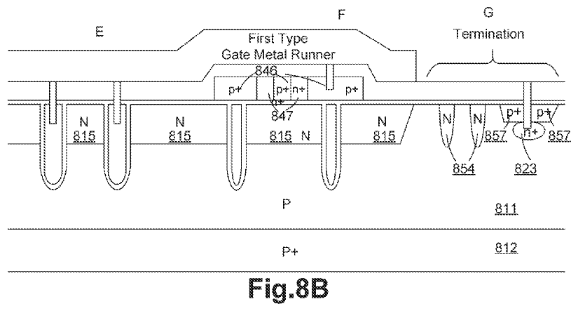

Please refer to FIG. 8A for another E-F-G cross-section view of FIG. 3, which is comprised of single trench gate MOSFET (P channel) with trenched termination. The structure is same to that illustrated in FIG. 6A, except that the doping type in substrate 812, epitaxy layer 811, regions 815, 846 and 847 is opposite to that disclosed in FIG. 6A.

Please refer to FIG. 8B for another E-F-G cross-section view of FIG. 3, which comprises a single trench gate MOSFET (P channel) with multiple P body floating rings. The structure is same to that illustrated in FIG. 6B, except that the doping type in substrate 812, epitaxy layer 811, regions 815, 823, 846, 847, 854 and 857 is just opposite to that disclosed in FIG. 6B.

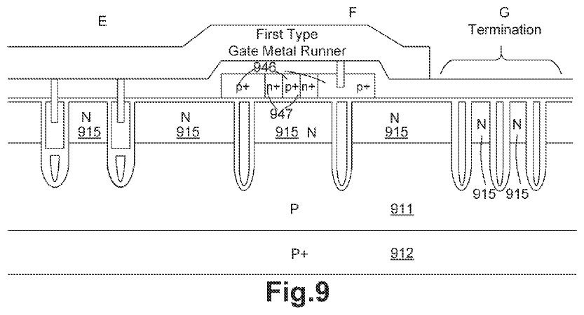

Please refer to FIG. 9 for another E-F-G cross-section view of FIG. 3, which comprises a shielded gate trench MOSFET (P channel) with trench filed plate as termination. The structure is same to that illustrated in FIG. 7, except that the doping type in substrate 912, epitaxy layer 911, regions 915, 946 and 947 is just opposite to that disclosed in FIG. 7.

As an alternative to the exemplary embodiment illustrated and described above, the semiconductor power device can also be formed as a trench IGBT. In the case of a trench IGBT, the heavily doped N+ substrate should be replaced by an N+ buffer layer extending over a heavily doped P+ substrate. In this regards, the terminology, such as “source”, “body”, “drain” should be accordingly replaced by “emitter”, “base”, “collector”.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A semiconductor power device integrated with Gate-Source ESD clamp diodes comprising a substrate of a first conductivity type;
an epitaxial layer of said first conductivity type grown on said substrate, wherein said epitaxial layer having a lower doping concentration than said substrate;
a plurality of transistor cells in an active area, and multiple back to back Zener diodes with alternating doped regions of a first conductivity type next to a second conductivity type in said Gate-Source ESD clamp diodes formed on a poly-silicon layer, wherein:
said trench semiconductor power device further comprises:
a plurality of first type trenched gates surrounded by source regions of said first conductivity type encompassed in body regions of said second conductivity type;
a plurality of trenched source-body contacts opened through said source regions and extending into said body regions, filled with a contact metal plug therein and connected to a front metal serving as a source metal pad;
said Gate-Source ESD clamp diodes further comprises:
a gate metal pad connected to first type gate metal runner with said poly-silicon layer underneath as anode electrode of said gate-source ESD clamp diodes surrounding a peripheral region of said semiconductor power device;
a first type Gate-Source ESD clamp diode connected between said gate metal pad and said source metal pad;
a second type Gate-Source ESD clamp diode connected between said source metal pad and said first type gate metal runner; and
said first type gate metal runner is extended into said active area and connected to said first type trench gates for gate resistance reduction.

2. The semiconductor power devices of claim 1, wherein said first type gate metal runner extended into active area connecting to said first type trenched gates from any portions of said first type gate metal runner surrounding said peripheral region of power device.

3. The semiconductor power devices of claim 1, wherein said first type gate runner extended to active area and connected to said first type trenched gates through at least one second type gate metal runner without having said poly-silicon layer underneath.

4. The semiconductor power device of claim 1 further comprising:
said source metal pad connected to at least one source metal runner disposed between said gate metal pad and said gate metal runner, and separated from said gate metal pad and said gate metal runner by a metal gap, wherein said source metal runner does not have said first type trenched gates underneath;
a third type Gate-Source ESD clamp diode connected between said gate metal pad and said source metal runner; and
a fourth type Gate-Source ESD clamp diode connected between said source metal runner and said gate metal runner.

5. The semiconductor power device of claim 1, wherein each of said alternating doped regions of said Gate-Source ESD clamp diodes has a closed ring structure.

6. The semiconductor power device of claim 1, wherein said body regions are formed underneath said Gate-Source ESD clamp diodes, and are further extended between every two adjacent of second type trenched gates functioning as etch-buffer trenched gates, and said etch-buffer trenched gates are penetrating through said body regions and disposed right below trenched ESD contacts in said Gate-Source ESD clamp diodes, wherein said etch-buffer trenched gates have trench width greater than said trenched ESD contacts for prevention of gate-body shortage.

7. The semiconductor power device of claim 1 further comprising:
at least one body-dopant region of said second conductivity type with floating voltage in a termination area, wherein said body-dopant region is formed simultaneously as said body regions;
a source-dopant region of said first conductivity type formed near an edge of said semiconductor power device, wherein said source-dopant region is formed simultaneously as said source regions;
a trenched drain contact filled with said contact metal plug and penetrating through said source-dopant region, and further extended into said semiconductor silicon layer;
an ohmic contact doped region of said second conductivity type surrounding at least bottom of said trenched drain contact underneath said source-dopant region; and
said ohmic contact doped region has a higher doping concentration than said body regions.

8. The semiconductor power device of claim 8, wherein there is no front metal covering a top surface of said contact metal plug in said trenched drain contact.

9. The semiconductor power device of claim 1 further comprising multiple third type trenched gates having floating voltage in a termination area.

10. The trench semiconductor power device of claim 1, wherein said contact metal plug is a tungsten layer padded with a barrier metal layer of Ti/TiN or Co/TiN.

11. The trench semiconductor power device of claim 1, wherein said front metal is Al alloys overlying a resistance-reduction layer of Ti or Ti/TN.

13. The power semiconductor device of claim 1, wherein said first type trench gates are single trench gate.

14. The power semiconductor device of claim 1, wherein said first type trench gates are shielded trenched gate having dual gate electrodes comprising a gate electrode disposed in the upper portion and a shielded gate electrode disposed in the lower potion, wherein said gate electrode and said shielded gate electrode insulated from each other by an inter-electrode insulation layer; and said first type gate metal runner is extended into said active area and connected to said gate electrode of said first type trenched gates.

15. The power semiconductor device of claim 1, wherein said first conductivity type is N type and second conductivity type is P type.

16. The power semiconductor device of claim 1, wherein said first conductivity type is P type and second conductivity is N type.
